(19) United States
(12) Patent Application Publication
(10) Pub. No.: US 2024/0248400 A1
(43) Pub. Date: Jul. 25, 2024

(54) DIELECTRIC FILM FORMING COMPOSITION CONTAINING ACYL GERMANIUM COMPOUND

(71) Applicant: Fujifilm Electronic Materials U.S.A., Inc., N. Kingstown, RI (US)

(72) Inventors: Binod B. De, Attleboro, MA (US); Sanjay Malik, Attleboro, MA (US); William A. Reinerth, Riverside, RI (US); Stephanie Dilocker, Attleboro, MA (US)

(21) Appl. No.: 18/542,862

(22) Filed: Dec. 18, 2023

Related U.S. Application Data
(60) Provisional application No. 63/437,151, filed on Jan. 5, 2023.

(51) Int. Cl. G03F 7/031; C08G 73/10; C08J 5/18; G03F 7/037; G03F 7/20

(52) U.S. Cl. CPC G03F 7/031; C08G 73/1032; C08G 73/1067; C08J 5/18; G03F 7/037; G03F 7/2002; C08J 2379/08; H01L 21/31144

(57) ABSTRACT

This disclosure relates to a dielectric film forming composition that includes at least one resin; and at least one acyl germanium compound, as well as related processes, films, dry film structures, and articles.

### CROSS-REFERENCE TO RELATED APPLICATION

The present application claims priority to U.S. Provisional Application Ser. No. 63/437,151, filed on Jan. 5, 2023, the contents of which are hereby incorporated by reference in their entirety.

### FIELD OF THE DISCLOSURE

The present disclosure relates to dielectric film forming compositions containing an acyl germanium compound, as well as related processes, films, dry film structures, and articles.

### BACKGROUND OF THE DISCLOSURE

Dielectric material requirements for semiconductor packaging applications are continuously evolving. The trend in electronic packaging continues to move towards faster processing speeds, increased complexity and higher packing density while maintaining a high level of reliability. As electronic packaging technology advances and chips continue to shrink in size, the demand for innovative and high-performance resin composition is growing. In order to cope with high resolution, various proposals have been made for a photosensitive dielectric composition. A photoinitiator having high sensitivity in longer wavelengths may be beneficial in some cases when used in photosensitive composition using Laser Direct Imaging (LDI) technique.

### SUMMARY OF THE DISCLOSURE

This disclosure is based on the unexpected discovery that certain acyl germanium compounds can be used as a photoinitiator or a photosensitizer in a photosensitive dielectric film forming composition such that the composition can be developed at a relatively long UV wavelength (e.g., about 405 nm) to form a dielectric film. The acyl germanium compounds can be non-toxic and can significantly improve the resolution of the dielectric film thus formed. As such, the dielectric film thus formed can have excellent pattern shape and film hardness.

In one aspect, this disclosure features dielectric film forming compositions containing at least one resin (e.g., a polymer); and at least one acyl germanium compound.

In some embodiments, the dielectric film forming compositions described herein can further include at least one ethylenically unsaturated polymerizable compound, at least one thiol compound, at least one siloxane compound, or mixtures thereof.

In some embodiments, the dielectric film forming compositions described herein can further contain a radical initiator (e.g., a photoinitiator) different from the acyl germanium compound. In some embodiments, the radical initiator does not generate free radicals when exposed at a wavelength of UV light (e.g., because the radical initiator itself does not substantially absorb the UV light at that wavelength). In such cases, it is believed that the acyl germanium compound described herein can act as a sensitizer and facilitate the generation of free radicals from the above radical initiator by synergistic effects.

In some embodiments, the dielectric film forming compositions described herein can further contain a photosensitizer different from the acyl germanium compound, where the photosensitizer can absorb light in the wavelength range of from about 150 nm to about 600 nm (e.g., at about 405 nm).

In some embodiments, the resin described herein can include a fully imidized polyimide optionally containing a functional group, a cyclized rubber, a cyclic olefin polymer optionally containing a functional group, a polyphenylene ether, an acrylic compound, a cyanate ester compound, a polybenzoxazole precursor polymer, a novolac polymer, an epoxy phenol novolac polymer, or an alkali soluble polyimide. In some embodiments, the resin is selected from a group consisting of not fully imidized polyimide resins (may be referred to in this disclosure as precursor polyimides) which may contain functional groups.

In some embodiments, the dielectric film forming compositions described herein can optionally include one or more of the following components:
a) one or more adhesion promoters;
b) one or more corrosion inhibitors;
c) one or more surfactants;
d) one or more fillers or particles;
e) one or more additives comprising a dye, a mixture of dyes, a pigment or a mixture of pigments; and
f) one or more metal-containing (meth)acrylate compounds.

In another aspect, the present disclosure features processes for preparing a patterned dielectric film, the processes including a) depositing a dielectric film forming composition described herein on a substrate to form a dielectric film; b) exposing the dielectric film to radiation or heat or a combination of radiation or heat; and c) patterning the dielectric film to form a patterned dielectric film having openings.

In another aspect, the present disclosure features processes for forming a three-dimensional object, the processes including: a) providing a substrate containing metal wire structures (which can contain copper) that form a network of lines and interconnects on the substrate; b) depositing a dielectric film forming composition described herein on the substrate to form a dielectric film; and c) exposing the dielectric film to radiation or heat or a combination of radiation and heat.

In another aspect, the present disclosure features processes for preparing a three-dimensional object (e.g., an object containing a metal layer), the processes including: a) depositing a dielectric film forming composition described herein on a substrate to form a dielectric film; b) exposing the dielectric film to radiation or heat or a combination of radiation and heat; c) patterning the dielectric film to form a patterned dielectric film having openings; d) optionally depositing a seed layer on the patterned dielectric film; and e) depositing a metal layer in at least one opening in the patterned dielectric film.

In another aspect, the present disclosure features dry film structures that include a carrier substrate and a dielectric film supported by the carrier substrate, in which the dielectric film is prepared from a dielectric film forming composition described herein.

In another aspect, the present disclosure features processes for preparing a dry film structure, the processes containing: (a) coating a carrier substrate with a dielectric film forming composition described herein to form a coated composition; (b) drying the coated composition to form a dielectric layer; and (c) optionally applying a protective layer to the dielectric layer to form the dry film structure.

In another aspect, the present disclosure features processes of generating a dielectric film on a substrate having a copper pattern, the processes containing: depositing a dielectric film forming composition described herein onto a substrate having a copper pattern to form a dielectric film, in which the difference in height between the highest and lowest points on a surface of the dielectric film is at most about 2 microns.

In still another aspect, the present disclosure describes a method for manufacturing a cured film comprising: exposing a photosensitive dielectric film described herein with electromagnetic radiation in the range from about 150 to about 600 nm, an electron beam, or X-ray; developing the dielectric film after the exposure with a developer to obtain a pattern, and manufacturing the cured film by heating the patterned film.

In yet another aspect, the present disclosure features three-dimensional objects prepared by the process described herein. In some embodiments, the object includes the dielectric film in at least two or three stacks.

### DETAILED DESCRIPTION OF THE DISCLOSURE

In general, the present disclosure relates to dielectric film forming compositions. In some embodiments, the dielectric film forming compositions described herein can be photosensitive. For example, the dielectric film forming compositions described herein can be sensitive to electromagnetic or actinic radiation in the wavelength range of from about 150 nm to 600 nm (e.g., 405 nm), electron beam, or X-ray, thereby resulting in solubility change (e.g., solubility increase or decrease) in a suitable developer (e.g., a TMAH solution).

In some embodiments, the present disclosure provides dielectric film forming compositions containing at least one (e.g., two, three, or four) resin (e.g., a polymer such as a dielectric polymer), and at least one (e.g., two, three, or four) acyl germanium compound according to structure (I),

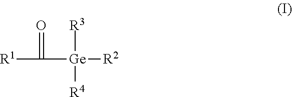

wherein R¹ is C₁-C₁₂ alkyl, C₂-C₁₂ alkenyl, C₄-C₁₈ cycloalkyl, C₆-C₂₂ aryl, or C₆-C₂₂ heteroaryl; each of R², R³, R⁴, independently, is C₁-C₁₂ alkyl, C₂-C₁₂ alkenyl, C₄-C₁₈ cycloalkyl, C₆-C₂₂ aryl, C₆-C₂₂ heteroaryl, or —C(O)R, in which R is C₁-C₄ alkyl, C₅-C₁₂ cycloalkyl, C₆-C₁₈ aryl, or C₆-C₁₈ heteroaryl; and each of alkyl, alkenyl, cycloalkyl, aryl, or heteroaryl, independently, is optionally substituted by at least one (e.g., two or three) C₁-C₄ alkyl, halogen, C₁-C₄ haloalkyl, —OR⁵, —OC(O)R⁵, or —COOR⁵, where R⁵ is H, C₁-C₄ alkyl, C₅-C₁₂ cycloalkyl, C₆-C₁₈ aryl, or C₆-C₁₈ heteroaryl. In some embodiments, the acyl germanium compounds described herein can include one acyl group (i.e., monoacyl germanium compounds), two acyl groups (i.e., diacyl germanium compounds), three acyl groups (i.e., triacyl germanium compounds), or four acyl groups (i.e., tetraacyl germanium compounds).

Examples of alkyl groups described herein include methyl, ethyl, propyl, isopropyl, and butyl. Examples of alkenyl groups described herein include vinyl and allyl. Examples of cycloalkyl groups described herein include cyclopentyl and cyclohexyl. Examples of aryl groups described herein include phenyl, naphthyl, pyrenyl, anthryl, and phenanthryl. Examples of heteroaryl groups described herein include furyl, furylene, fluorenyl, pyrrolyl, thienyl, oxazolyl, imidazolyl, thiazolyl, pyridinyl, pyrimidinyl, quinazolinyl, quinolyl, isoquinolyl, and indolyl.

Suitable examples of the compounds of structure (I) include, but not limited to, (2,4,6-trimethylbenzoyl)triethylgermanium, (2,4,6-trimethylbenzoyl)tripropylgermanium, (2,4,6-trimethylbenzoyl)tributylgermanium, (2,6-dimethoxybenzoyl)triethylgermanium, (2.6-dimethoxybenzoyl)tripropylgermanium, (2,6-dimethoxybenzoyl)tributylgermanium, bisbenzoyldiethylgermanium, bisbenzoyldipropylgermanium, bis(4-methoxybenzoyl)diethylgermanium, bis(2,4,6-trimethylbenzoyl)diethylgermanium, trisbenzoylethylgermanium, tris(2,4,6-trimethylbenzoyl)ethylgermanium and the like. A commercial example of an acyl germanium compound is Ivocerin (i.e., bis(4-methoxybenzoyl)diethylgermanium). Other examples of such acyl germanium compounds are disclosed in, e.g., U.S. Pat. Nos. 7,605,190 and 9,532,930, the entire contents of which are hereby incorporated by reference.

In some embodiments, the acyl germanium compound is in an amount of from at least about 0.05 wt % (e.g., at least about 0.1 wt %, at least about 0.2 wt %, at least about 0.4 wt %, at least about 0.5 wt %, at least about 0.6 wt %, at least about 0.8 wt %, at least about 1 wt %, at least about 1.5 wt %, or at least about 2 wt %) to at most about 20 wt % (e.g., at most about 18 wt %, at most about 16 wt %, at most about 15 wt %, at most about 14 wt %, at most about 12 wt %, at most about 10 wt %, at most about 8 wt %, at most about 6 wt %, at most about 5 wt %, at most about 4 wt %, at most about 2 wt %, or at most about 1 wt %) of the solid weight of a dielectric film forming composition described herein. As used herein, the solid weight of a dielectric film forming composition refers to the total weight of the solids in such a composition (i.e., without any solvent).

Without wishing to be bound by theory, it is believed that a dielectric film forming composition containing an acyl germanium compound described herein (either alone or in combination with an initiator different from the acyl germanium compound) can be developed at a relatively long UV wavelength (e.g., about 405 nm) to form a dielectric film. It is surprising that the dielectric film thus formed have significantly improved resolution and excellent pattern shape while being non-toxic to the environment.

The dielectric film forming compositions described herein can optionally contain at least one (e.g., two, three, or four) radical initiator different from the acyl germanium described herein. As used herein, a radical initiator refers to a compound capable of generating free radicals that can initiate radical polymerization or crosslinking upon heating or irradiation with light at a certain wavelength range (e.g., from about 150 nm (e.g., about 157 nm) or about 600 nm). In some embodiments, the wavelength range is selected such that the radical initiator has absorption and the radically polymerizable monomer does not have substantial absorption. A photo-radical initiator (also referred to herein as a photoinitiator) and a thermal-radical initiator (also referred to herein as a thermal initiator) are examples of a radical initiator. In some embodiments, a photo-radical initiator is preferable.

In some embodiments, the amount of the radical initiator (e.g., a photoinitiator) is from at least about 0.1 wt % (e.g., at least about 0.2 wt %, at least about 0.5 wt %, at least about 0.8 wt %, at least about 1 wt %, at least about 1.5 wt %, at least about 2 wt %, at least about 3 wt %, at least about 4 wt %, or at least about 5 wt %) to at most about 10 wt % (e.g., at most about 9 wt %, at most about 8 wt %, at most about 7 wt %, at most about 6 wt %, at most about 5 wt %, at most about 4 wt %, at most about 3 wt %, at most about 2 wt %, or at most about 1 wt %) of the solid weight of a dielectric film forming composition described herein.

In some embodiments, a photoinitiator has photosensitivity to rays ranging from an ultraviolet ray region to a visible region. In some embodiments, the photoinitiator can be an activator which produces a free radical by some action with a photo-excited sensitizer.

One example of a photoinitiator is an oxime ester of structure (II),

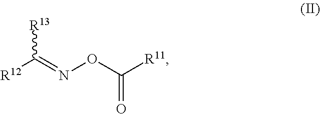

wherein each of R¹¹ and R¹², independently, is substituted or unsubstituted C₁-C₁₂ alkyl, substituted or unsubstituted C₄-C₁₈ cycloalkyl, substituted or unsubstituted C₆-C₂₂ aryl, or substituted or unsubstituted C₆-C₂₂ heteroaryl; and R¹³ is a UV absorbing functional group (e.g., a substituted or unsubstituted C₆-C₂₂ aryl or a substituted or unsubstituted C₆-C₂₂ heteroaryl). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O)R′, or —COOR′, where R′ is H, C₁-C₄ alkyl, C₅-C₁₂ cycloalkyl, C₆-C₁₈ aryl, or C₆-C₁₈ heteroaryl.

Examples of oxime esters of formula (II) include, but are not limited to,

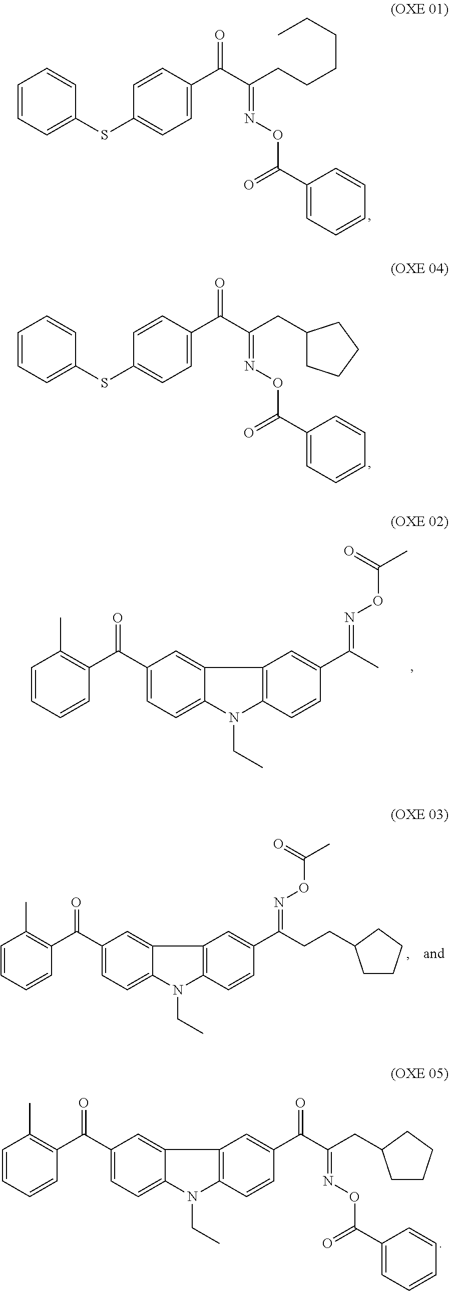 [SMILES: CCCCCC/C(=N\OC(=O)c1ccccc1)C(=O)c1ccc(Sc2ccccc2)cc1 ; O=C(O/N=C(\CC1CCCC1)C(=O)c1ccc(Sc2ccccc2)cc1)c1ccccc1 ; CCn1c2ccc(C(=O)c3ccccc3C)cc2c2cc(/C(C)=N/OC(C)=O)ccc21 ; CCn1c2ccc(C(=O)c3ccccc3C)cc2c2cc(/C(CCC3CCCC3)=N/OC(C)=O)ccc21 ; CCn1c2ccc(C(=O)/C(CC3CCCC3)=N/OC(=O)c3ccccc3)cc2c2cc(C(=O)c3ccccc3C)ccc21]

Another example of a photoinitiator is an organic compound of structure (III):

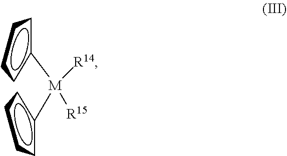

wherein M is selected from the group consisting of a titanium atom, a zirconium atom, and a hafnium atom; and each of R¹⁴ and R¹⁵, independently, is selected from the group consisting of substituted or unsubstituted C₁-C₁₂ alkyl, substituted or unsubstituted C₄-C₁₈ cycloalkyl, substituted or unsubstituted C₆-C₂₂ aryl, substituted or unsubstituted C₆-C₂₂ heteroaryl, substituted or unsubstituted C₆-C₂₂ heteroaryl, and substituted or unsubstituted alkylsulfonyloxy (e.g., a substituted or unsubstituted C₁-C₁₂ alkylsulfonyloxy group). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O)R′, or —COOR′, where R′ is H, C₁-C₄ alkyl, C₅-C₁₂ cycloalkyl, C₆-C₁₈ aryl, or C₆-C₁₈ heteroaryl.

Commercial examples of photoinitiators include, but are not limited to, IRGACURE-784, IRGACURE OXE 01, IRGACURE OXE 02, IRGACURE OXE 03, IRGACURE OXE 04, and IRGACURE OXE 05 available from BASF; ADEKA OPTOMER N-1919, ADEKA ARKLS NCI-831, and ADEKA ARKLS NCI-930 available from ADEKA Corporation. Examples of other photoinitiators are disclosed in, e.g., EP patent numbers 3,492, 982, the entire contents of which are hereby incorporated by reference.

Examples of thermal initiators include, but are not limited to, benzoyl peroxide, cyclohexanone peroxide, lauroyl peroxide, tert-amyl peroxybenzoate, tert-butyl hydroperoxide, di(tert-butyl)peroxide, dicumyl peroxide, cumene hydroperoxide, succinic acid peroxide, di(n-propyl)peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

Other examples of radical photopolymerization initiators include benzophenone derivatives such as benzophenone, methyl o-benzoyl benzoate, 4-benzoyl-4′-methyl diphenyl ketone, dibenzyl ketone, and fluorenone; acetophenone derivatives such as 2,2′-diethoxyacetophenone, 2-hydroxy-2-methyl propiophenone, 1-hydroxy cyclohexyl phenyl ketone; thioxanthone derivatives such as thioxanthone, 2-methylthioxanthone, 2-isopropylthioxanthone, diethylthioxanthone, and the like; benzyl derivatives such as benzyl, benzyl dimethyl ketal, benzyl-beta-methoxyethyl acetal and the like; benzoin derivatives such as benzoin, benzoin methyl ether and the like; benzoin derivatives such as benzoin, benzoin methyl ether and the like; 1-phenyl-1,2-butanedione-2-(o-methoxycarbonyl) oxime, 1-phenyl-1,2-propanedione-2-(o-methoxycarbonyl) oxime, 1-phenyl-1,2-propanedione-2-(o-ethoxycarbonyl) oxime, 1-phenyl-1,2-propanedione-2-(o-benzoyl) oxime, oximes such as 3-diphenylpropanetrione-2-(o-ethoxycarbonyl) oxime, 1-phenyl-3-ethoxypropanetrione-2-(o-benzoyl) oxime; N-arylglycines such as N-phenylglycine, peroxides such as benzoyl peroxide, aromatic biimidazoles, and the like. Furthermore, these may be used alone or as a mixture of 2 or more types.

In some embodiments, the dielectric film forming compositions described herein can include at least one (e.g., two, three, or four) photosensitizer different from the acyl germanium compound, where the photosensitizer can absorb light in the wavelength range of from about 150 nm to about 600 nm (e.g., at about 405 nm). Examples of suitable photosensitizers that can be used in the dielectric film forming composition include benzophenone compounds, thioxanthone compounds, anthraquinone compounds, anthracene compounds, coumarine compounds, and mixtures thereof. Specific examples of photosensitizers include, but are not limited to, 9-methylanthracene, 9,10-dibutoxyanthracene, 9,10-diethoxyanthracene, anthracenemethanol, acenaphthylene, thioxanthone, methyl-2-naphthyl ketone, 4-acetylbiphenyl, and 1,2-benzofluorene. Examples of other photosensitizers are disclosed in, e.g., U.S. Application Publication No. 2022/0171285, the entire contents of which are hereby incorporated by reference. In some embodiments, the acyl germanium compounds described herein can serve as a photosensitizer.

In some embodiments, the amount of a photosensitizer other than an acyl germanium compound is from at least about 0.01 wt % (e.g., at least about 0.05 wt %, at least about 0.1 wt %, or at least about 0.5 wt %) to at most about 1 wt % (e.g., at most about 0.8 wt %, at most about 0.6 wt %, at most about 0.5 wt %, at most about 0.4 wt %, at most about 0.2 wt %, or at most about 0.1 wt %) of the solid weight of a dielectric film forming composition described herein.

In some embodiments, the dielectric film forming compositions described herein can optionally include at least one (e.g., two, three, or four) crosslinker. In some embodiments, the crosslinker can include an ethylenically unsaturated polymerizable compound (e.g., an ethylenically unsaturated photopolymerizable compound), a thiol compound, a siloxane compound, a metal-containing (meth)acrylate compound, or mixtures thereof.

In some embodiments, the crosslinker described herein can include a multifunctional thiol compound containing at least two thiol groups. Examples of such thiol compounds include, but are not limited to, trimethylolpropane tris(mercaptoacetate), pentaerythritol tetrakis(mercaptoacetate), trimethylolpropane tris(3-mercaptopropionate), pentaerythritol tetrakis(3-mercaptopropionate), dipentaerythritol hexakis(3-mercaptopropionate), tris[2-(3-mercaptopropionyloxy)ethyl]isocyanurate, ethoxylated trimethylolpropane tri-3-mercaptopropionate, propylene glycol-3-mercaptopropionate 800, trimethylolpropane tris(4-sulfanylcyclohexanecarboxylate), pentaerythritol tetrakis(4-sulfanylcyclohexanecarboxylate), and the like. Other examples of such thiol compounds are disclosed in, e.g., U.S. Pat. No. 9,695,284, the entire contents of which are hereby incorporated by reference.

In some embodiments, the crosslinker described herein can include an ethylenically unsaturated polymerizable compound containing at least two (meth)acrylate groups. In some embodiments, the crosslinker is selected from the group consisting of 1,6-hexanediol di(meth)acrylate, tetraethyleneglycol di(meth)acrylate, 1,12-dodecanediol di(meth)acrylate, 1,3-butylene glycol di(meth)acrylate, 1,4-butanediol di(meth)acrylate, cyclohexane dimethanol di(meth)acrylate, polyethylene glycol di(meth)acrylate, propoxylated (3) glycerol tri(meth)acrylate, ethoxylated bisphenol-A-di(meth)acrylate, trimethylolpropane tri(meth)acrylate, ditrimethylolpropane tetra(meth)acrylate, pentaerythritol tri(meth)acrylate, pentaerythritol tetra(meth)acrylate, dipentaerythritol penta-/hexa-(meth)acrylate, isocyanurate tri(meth)acrylate, bis(2-hydroxyethyl)-isocyanurate di(meth)acrylate, 1,3-butanediol tri(meth)acrylate, 1,4-butanediol tri(meth)acrylate, neopentyl glycol di(meth)acrylate, (meth)acrylate modified-urea-formaldehyde resins, (meth)acrylate modified melamine-formaldehyde resins, and (meth)acrylate modified cellulose. Other examples of such compounds are disclosed in, e.g., U.S. Pat. Nos. 10,036,952 and 10,563,014, and U.S. Application Publication No. 2015/0219990, EP Patent No 3,492,982; the entire contents of which are hereby incorporated by reference.

In some embodiments, the crosslinker described herein can include a multifunctional siloxane compound containing at least two siloxane groups, such as disiloxanes. Examples of such disiloxane compounds include, but are not limited to, 1,1,3,3-tetramethyldisiloxane, 1,1,3,3,5,5-hexamethyltrisiloxane, 1,2-bis(tetramethyldisiloxanyl)ethane and the like. In some embodiments, a multifunctional siloxane can be a cyclic compound of structure (IVa), where each R₂₂ is independently a hydrogen or C₁-C₄ alkyl group and i is an integer of 0 to 3; or a silsesquioxane compound of structure (IVb), where each R₂₃ independently is a —O—Si(R₂₄)₂H group, and each R₂₄ is independently a C₁-C₄ alkyl group.

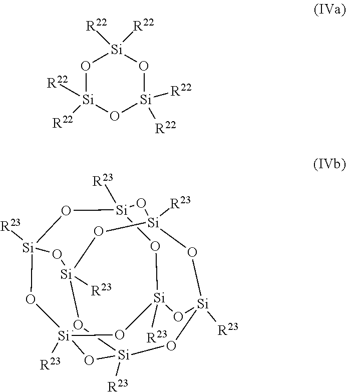

In some embodiments, the crosslinker described herein can a metal-containing (meth)acrylate (MCA) compound. As used herein, the term “(meth)acrylate” refers to both acrylate compounds and methacrylate compounds. Examples of suitable MCAs include, but are not limited to, titanium tetra(meth)acrylate, zirconium tetra(meth)acrylate, hafnium tetra(meth)acrylate, titanium butoxide tri(meth)acrylate, titanium (meth)acryloxyethylacetoacetate triisopropoxide, titanium tris(2-ethylhexanoate) (carboxyethyl (meth)acrylate), titanium dibutoxide di(meth)acrylate, titanium tributoxide (meth)acrylate, titanium oxide di(meth)acrylate, zirconium butoxide tri(meth)acrylate, zirconium dibutoxide di(meth)acrylate, zirconium tributoxide (meth)acrylate, zirconium oxide di(meth)acrylate, hafnium butoxide tri(meth)acrylate, hafnium dibutoxide di(meth)acrylate, hafnium tributoxide (meth)acrylate, hafnium oxide di(meth)acrylate, titanium (2,4-pentanedionate) tri(carboxyethyl (meth)acrylate), titanium tetra(carboxyethyl (meth)acrylate), zirconium tetra(carboxyethyl (meth)acrylate), hafnium tetra(carboxyethyl (meth)acrylate), titanium butoxide tri(carboxyethyl (meth)acrylate), titanium dibutoxide di(carboxyethyl (meth)acrylate), titanium tributoxide (carboxyethyl (meth)acrylate), titanium oxide di(carboxyethyl (meth)acrylate), zirconium butoxide tri(carboxyethyl (meth)acrylate), zirconium dibutoxide di(carboxyethyl (meth)acrylate), zirconium tributoxide (carboxyethyl (meth)acrylate), zirconium oxide di(carboxyethyl (meth)acrylate), zirconium bis(2-ethylhexanoate) di(carboxyethyl (meth)acrylate), zirconium bis(2,4-pentanedionate) di(carboxyethyl (meth)acrylate), hafnium butoxide tri(carboxyethyl (meth)acrylate), hafnium dibutoxide di(carboxyethyl (meth)acrylate), hafnium tributoxide (carboxyethyl (meth)acrylate), and hafnium oxide di(carboxyethyl (meth)acrylate).

In some embodiments, the crosslinker described herein can be in an amount of from at least about 0.5 wt % (e.g., at least about 1 wt %, at least about 2 wt %, at least about 3 wt %, at least about 4 wt %, at least about 5 wt %, at least about 6 wt %, at least about 7 wt %, at least about 8 wt %, at least about 9 wt %, at least about 10 wt %) to at most about 25 wt % (e.g., at most about 24 wt %, at most about 22 wt %, at most about 20 wt %, at most about 18 wt %, at most about 16 wt %, at most about 15 wt %, at most about 14 wt %, at most about 12 wt %, at most about 10 wt %, at most about 8 wt %, at most about 6 wt %, or at most about 5 wt %) of the solid weight of a dielectric film forming composition described herein.

In some embodiments, the dielectric film forming compositions described herein includes at least one (e.g., two, three, or four) resin (e.g., a polymer resin). In some embodiments, the resin can include a fully imidized polyimide optionally containing a functional group; a cyclized rubber; a cyclic olefin polymer optionally containing a functional group; a polyphenylene ether; an acrylic compound; a cyanate ester compound; a polybenzoxazole precursor polymer; a novolac polymer; an epoxy phenol novolac polymer; or an alkaline soluble polyimide. In some embodiments, the functional group on a polymer can be an acidic group, such as a carboxylic acid group, a hydroxyl group, or a sulfonic acid group.

In some embodiments, the fully imidized polyimide described herein can be a polymer of structure (V):

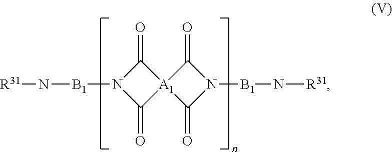

wherein R³¹ is an end group (e.g., a functional or non-functional end group), n is an integer greater than 5 (e.g., 5-100), B1 is the nucleus of a precursor diamine and A1 is the nucleus of a precursor dianhydride. As used herein, when referring to the precursor diamine, “nucleus” refers to the moiety between two amine functional groups. When referring to the precursor dianhydride, “nucleus” refers to the moiety between two anhydride functional groups. Examples of such diamines and dianhydrides are disclosed in, e.g., U.S. Pat. No. 9,695,284, the entire contents of which are hereby incorporated by reference. Functional or non-functional acid anhydrides or acid chlorides can be used for endcapping of unreacted amine functionality on the amino-terminated polyamic acid.

Examples of suitable diamines that can be used to prepare the polymer of structure (V) include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl)propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl) benzidine, 3,3′-bis(trifluoromethyl) benzidine, 2,2-bis[4-(4-aminophenoxyphenyl)]hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy) phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene,4,4′-diamino-2,2′-bis(trifluoromethyl)biphenyl, and 9H-fluorene-2,6-diamine. Any of these diamines can be used individually or in combination in any suitable ratio to form a polyimide described herein.

Examples of suitable dianhydrides that can be used to prepare the polymer of structure (V) include, but are not limited to, 1-(3′,4′-dicarboxyphenyl)-1,3,3-trimethylindan-5,6-dicarboxylic acid dianhydride, 1-(3′,4′-dicarboxyphenyl)-1,3,3-trimethylindan-6,7-dicarboxylic acid dianhydride, 1-(3′,4′-dicarboxyphenyl)-3-methylindan-5,6-dicarboxylic acid dianhydride, 1-(3′,4′-dicarboxyphenyl)-3-methylindan-6,7-dicarboxylic acid anhydride, pyromellitic dianhydride, benzene-1,2,3,4-tetracarboxylic dianhydride, 2,3,5,6-naphthalenetetracarboxylic acid dianhydride, 2,3,6,7-naphthalenetetracarboxylic acid dianhydride, 1,4,5,8-naphthalenetetracarboxylic acid dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-,8,9,10-tetracarboxylic dianhydride, 3,4,9,10-perylenetetracarboxylic acid dianhydride, pyrazine-2,3,5,6-tetracarboxylic dianhydride, thiophene-2,3,4,5-tetracarboxylic dianhydride, 2,3,5,6-pyridinetetracarboxylic acid dianhydride, butane-1,2,3,4-tetracarboxylic acid dianhydride, 1,2,3,4-cyclopentanetetracarboxylic acid dianhydride, cyclobutane-1,2,3,4-tetracarboxylic acid dianhydride, cyclopentane-1,2,3,4-tetracarboxylic acid dianhydride, cyclohexane-1,2,4,5-tetracarboxylic acid dianhydride, norbornane-2,3,5,6-tetracarboxylic acid dianhydride, bicyclo[2.2.2]oct-7-ene-3,4,8,9-tetracarboxylic acid dianhydride, tetracyclo[4.4.1.0^{2,5} 0.0^{7,10}]undecane-1,2,3,4-tetracarboxylic acid dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, 3,3′,4,4′-diphenylsulfone tetracarboxylic dianhydride, 2,2′,3,3′-diphenylsulfone tetracarboxylic dianhydride, 2,3,3′,4′-diphenylsulfone tetracarboxylic dianhydride, 3,3′,4,4′-diphenylether tetracarboxylic dianhydride, 2,2′,3,3′-diphenylether tetracarboxylic dianhydride, 2,3,3′,4′-diphenylether tetracarboxylic dianhydride, 2,2-[bis(3,4-dicarboxyphenyl)]hexafluoropropane dianhydride, ethyleneglycol bis(anhydrotrimellitate), and 5-(2,5-dioxotetrahydro)-3-methyl-3-cyclohexene-1,2-dicarboxylic anhydride. Any of these tetracarboxylic acid dianhydrides can be used individually or in combination in any suitable ratio to form a polyimide described herein.

In some embodiments, the fully imidized polyimide mentioned herein is at least about 90% (e.g., at least about 95%, at least about 98%, at least about 99%, or about 100%) imidized.

In some embodiments, the weight average molecular weight of the fully imidized polyimide is at least about 20,000 Daltons (e.g., at least about 25,000 Daltons, at least about 30,000 Daltons, at least about 35,000 Daltons, at least about 40,000 Daltons, at least about 45,000 Daltons, at least about 50,000 Daltons, or at least about 55,000 Daltons) and/or at most about 100,000 Daltons (e.g., at most about 95,000 Daltons, at most about 90,000 Daltons, at most about 85,000 Daltons, at most about 80,000 Daltons, at most about 75,000 Daltons, at most about 70,000 Daltons, at most about 65,000 Daltons, or at most about 60,000 Daltons).

In some embodiments, the fully imidized polyimide is prepared by reaction of at least one diamine with at least one tetracarboxylic acid dianhydride. In some embodiments, the resulting polymer is soluble in the organic solvent of this disclosure to facilitate the formation of a dielectric film, such as a dielectric film with a planarized surface (e.g., the difference in the highest and lowest points on a top surface of the dielectric film is less than about 2 microns). Examples of fully imidized polyimides are known in the art and have been described, e.g., in U.S. Application Publication No. 2019/0077913, the entire contents of which are hereby incorporated by reference.

Methods to synthesize end-capped and non-endcapped PI precursor polymers are well known to those skilled in the art. Examples of such methods and PI precursor polymers are disclosed in, e.g., US Patent Nos. U.S. Pat. Nos. 2,731,447, 3,435,002, 3,856,752, 3,983,092, 4,026,876, 4,040,831, 4,579,809, 4,629,777, 4,656,116, 4,960,860, 4,985,529, 5,006,611, 5,122,436, 5,252,534, US5,4789,15, U.S. Pat. Nos. 5,773,559, 5,783,656, 5,969,055, 9,617,386, and US Application Publication No. US2004/0265731, US2004/0235992, and US2007/0083016, the entire contents of which are hereby incorporated by reference.

In some embodiments, the fully imidized polyimide described herein can be an alkali soluble polyimide which has at least one (e.g., two or three) functional group such as a carboxylic acid group, a hydroxyl group (e.g., a phenolic hydroxyl group), a sulfonic acid group, or a thiol group (e.g., at one end of a main chain or both, or at a side chain of the polymer). The term “alkali soluble” used herein means that the solubility in a 2.38 weight percent aqueous tetramethylammonium hydroxide solution at 25° C. is not less than about 0.1 g/100 mL.

In some embodiments, the polymer resins suitable for the dielectric film forming compositions described herein can include at least one (e.g., two, three, or four) dielectric polymer, such as a dielectric polymer containing an epoxy resin, a novolac resin, or a mixture of epoxy and novolac resins, a polybenzoxazole (PBO) precursor polymer, or a mixture thereof.

Examples of suitable epoxy resins that can be used as dielectric film materials are known to those skilled in the art and include those disclosed in, e.g., U.S. Pat. No. 4,882,245 and U.S. Application Publication No. 2006/0257785, the entire contents of which are hereby incorporated by reference.

Examples of suitable Novolac polymers described herein include those containing at least one photoactive o-quinonediazide compound and are known to those skilled in the art. Example of such Novolac polymers are disclosed in U.S. Pat. Nos. 5,413,894; 5,306,594; 4,959,292, 8,334,092; and 8,492,067; and U.S. Application Publication No. 2012/0296053 and 2012/0052438; the entire contents of which are hereby incorporated by reference.

In some embodiments, the resins in the dielectric film forming compositions described herein can include polyamic esters. The polyamic esters of the disclosure have a number average degree of polymerization of 5 to 100 and are synthesized by the polycondensation of monomers A and B as follows (1):

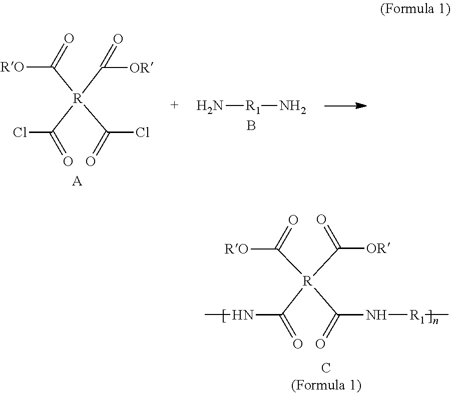

Monomer A is obtained by the reaction of a dianhydride compound with at an alcohol, R′OH, to yield a diester-diacid followed by conversion of the diacid-diester to a diester-diacid chloride by means of a suitable reagent (Formula 2):

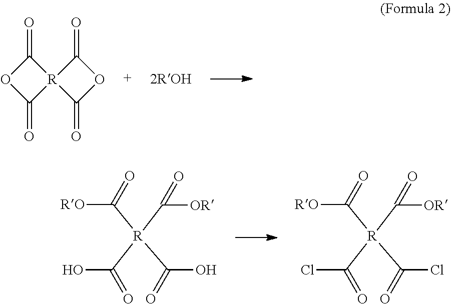

The group R represents a tetravalent aromatic group containing at least one 6-membered carbon ring wherein the four carbonyl groups are directly connected to is different carbon atoms of R and wherein each of two pairs of the four carbonyl groups is connected to adjacent carbon atoms. The dianhydride compound may be the same as shown earlier. The tetracarboxylic dianhydrides can be used singly or in combination and selection of the dianhydride compound is not limited to the compounds listed above. The group R′ contains at least one unsaturated group which may be a vinyl, allyl, acrylyl, methacryl, acetylenic, a cyano group, or other suitable radiation crosslinkable group.

Monomer B is a divalent diamine. Suitable diamines are the same as discussed earlier.

In some embodiments, the resins in the dielectric film forming compositions described herein can include a curable PBO (polybenzoxazole) precursor, such as a chemically amplified PBO precursor. The aqueous base solubility of the PBO precursor is reduced by protection of the aromatic hydroxyl group in the PBO precursor by attachment of acid labile groups. Restoration of the polymer alkali solubility is accomplished through the action of an acid produced by photolysis of a photoacid generator (PAG). The protecting groups can be any suitable acid labile group, such as acetals, ketals, carbonates, ethers, silyl ethers, moieties containing t-butyl esters, and combinations thereof. Using this concept, a positive-working photosensitive resin composition containing a PBO precursor bearing acid labile functional groups, a photoacid generator, and a solvent can be prepared and used to form a dielectric film. In some embodiments, after photolithographic processing, the patterned layer can be converted to a heat resistant polybenzoxazole coating by application of additional heating.

In some embodiments, a PBO precursor described herein can include acid labile functional groups having the following Structure (VI):

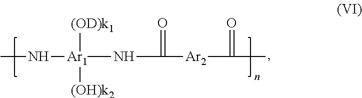

in which k₁ is an integer of 0, 1, or 2, k₂ is an integer of 0 or 1, and the sum of k₁ and k₂ is 0 or 2; Ar₁ is a tetravalent aromatic, aliphatic, or heterocyclic group, or a mixture of a tetravalent aromatic, aliphatic, or heterocyclic group and a divalent aromatic, aliphatic, or heterocyclic group, where the fraction of Ar₁ being a divalent group is 0-60 mole % and the sum of Ar₁ being a tetravalent group and a divalent group is 100 mole %; Ar₂ is a divalent aromatic, aliphatic, or heterocyclic group or siloxane group; D is a monovalent acid labile group and, in combination with the oxygen atom to which it is attached, is selected from the group consisting of acetals, ketals, carbonates, ethers, moieties containing t-butyl ester groups, and combinations thereof; and n is an integer from 20 to 200.

In some embodiments, Ar₁ includes the following moieties:

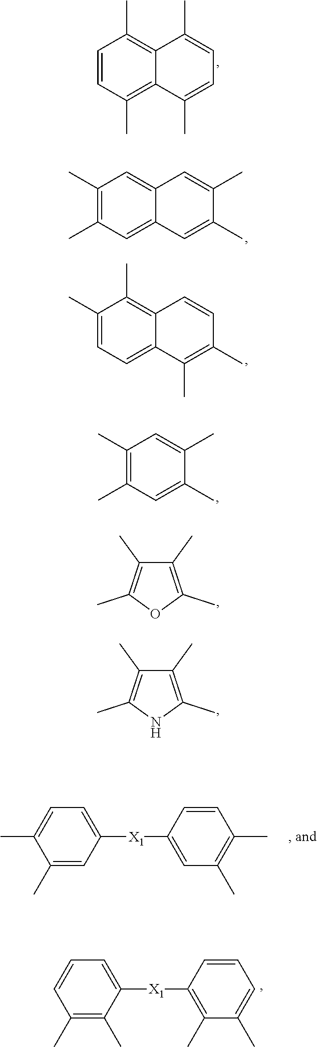

in which X₁ is —O—, —S—, —C(CF₃)₂—, —C(CH₃)₂—, —CH₂—, —SO₂—, —NHCO—, —C(O)—, —C(O)—C(O)—, —C(O)O—, or —(CH₂)m-Si(Z)₂—O—Si(Z)₂—(CH₂)ₘ-, Z is H or C₁-C₆ alkyl and m is an integer from 1 to 6.

In some embodiments, Ar₂ includes the following moieties:

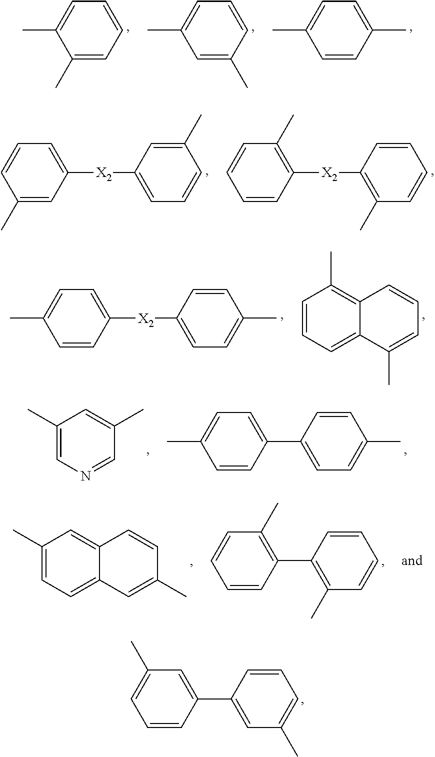

in which X₂ is —C(O)—C(O)—, —C(O)O—, or —(CH₂)p-Si(Z)₂—O—Si(Z)₂—(CH₂)ₚ-, Z is H or C₁-C₆ alkyl and p is an integer from 1 to 6. In some embodiments, the PBO precursor can contain one or more different Ar₁ and Ar₂ groups.

In some embodiments, D is any suitable monovalent acid labile group, such as acetals, ketals, carbonates, ethers, silyl ethers, moieties containing t-butyl esters, and combinations thereof. For example, D can include, but is not limited to, the moieties of the following formulas:

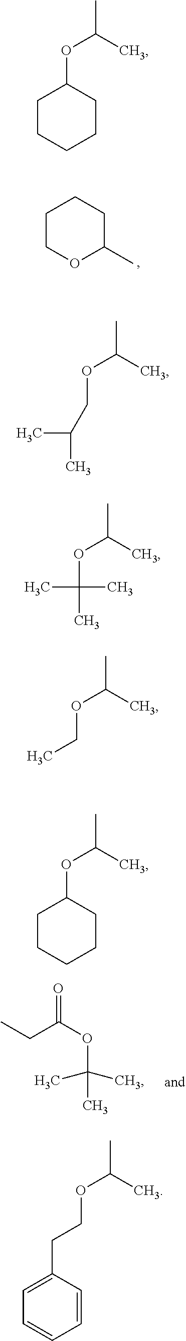

In some embodiments, D can be a monovalent quinone diazide ester compound formed between a PBO precursor having one or more phenolic hydroxyl groups and 1,2-naphthoquinone diazide-4-sulfonic acid, 1,2-naphthoquinone diazide-5-sulfonic acid, or a mixture thereof.

In some embodiments, when the dielectric film forming compositions described herein include a protected PBO precursor bearing acid labile functional groups, the compositions can also include a photoacid generator and a solvent. Optionally, the compositions can contain a photosensitizer, an adhesion promoter, a leveling agent, or other additives. After exposure to light, the photogenerated acid catalyzes deblocking of the protected PBO precursor, and converts it to an aqueous base soluble PBO precursor as shown in Reaction (1):

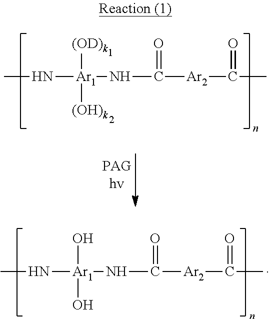

In general, any suitable photoacid generator compounds can be used to remove acid labile functional groups. For example, suitable photoacid generator compounds include triazine compounds, sulfonates, disulfones, onium salts, and mixtures thereof. Examples of suitable onium salts include iodonium, sulfonium, phosphonium, diazonium, sulfoxonium, and mixtures thereof.

The PBO precursor bearing acid labile functional groups, shown in Formula (VI) can be prepared from the reaction of a PBO precursor with a vinyl ether having the formula R¹═CH—OR² in the presence of an acid catalyst, wherein R¹ is (a) a linear, branched or cyclic alkylene group having 1 to 10 carbon atoms, (b) a linear, branched or cyclic haloalkylene group having 1 to 10 carbon atoms, or (c) an aralkylene group; R² is a linear, branched, cyclic alkyl, aralkyl, or linear or branched alkyl group bearing cycloalkyl, substituted cycloalkyl, aryl, and substituted aryl groups having 1 to 10 carbon atoms. Another suitable method of preparing the PBO precursor bearing acid labile functional groups is from the reaction of the PBO precursor with a di-t-butyl dicarbonate in the presence of a base. The PBO precursor bearing acid labile functional groups can also be synthesized by reacting the PBO precursor, an alcohol, and a t-butyl vinyl ether in the presence of an acid.

In some embodiments, the PBO precursor described herein may not include an acid labile functional group and can have Structure (VII) shown below:

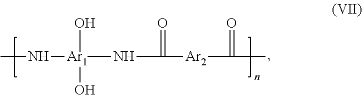

in which Ar₁, Ar₂, and n are defined above.

An acetal protected PBO precursor can be prepared by an acid catalyzed addition reaction of vinyl ethers and PBO precursors. Any suitable acid catalyst can be used for the reaction. Examples of suitable acid catalysts include hydrochloric acid, p-toluene sulfonic acid, and pyridium-p-toluene sulfonate. The acid catalyst can be added in amounts ranging from about 0.001% by weight to about 3.0% by weight. Several vinyl ethers with a range of activation energies toward acid induced deprotection can be used in this reaction. In some embodiments, acetal protected PBO precursors can be prepared using a process that includes the acid catalyzed reaction of a PBO precursor, t-butyl vinyl ether, and an alkyl-, alkylene-, cycloalkyl-, or arylalkyl-alcohol.

Methods to synthesize polybenzoxazole precursor polymers are known to those skilled in the art. Examples of such methods and PBO precursor polymers are disclosed in, e.g., U.S. Pat. Nos. 6,143,467, 7,195,849, 7,129,011, and 9,519,216, the entire contents of which are hereby incorporated by reference.

In some embodiments, the resins in the dielectric film forming compositions described herein can include at least one (e.g., two or three) polyphenylene ether (PPE). In some embodiments, the PPE can be a polymer of structure (VIII):

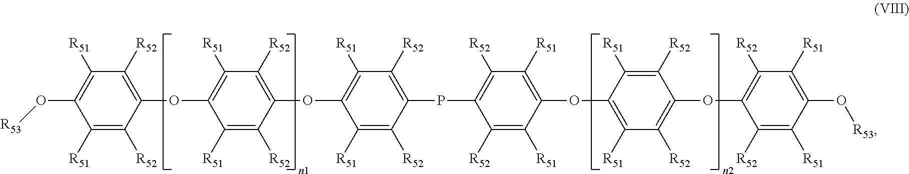

wherein each R₅₁, independently, represents an aliphatic hydrocarbon group having 1 to 6 carbon atoms; each R₅₂independently, represents a hydrogen atom, a halogen atom, or an aliphatic hydrocarbon group having 1 to 6 carbon atoms; each R₅₃, independently, represents an ethylenically unsaturated organic group; each of n1 and n2, independently, represents an integer from 0 to 20; and P represents a divalent group.

In some embodiments, the PPE can include at least one vinyl benzyl ether group or at least one meth(acrylate) group (e.g., in an end group R⁵³). Example of suitable PPEs are disclosed in, e.g., U.S. Pat. Nos. 9,402,310, 10,774,210, and 3,306,874; the entire contents of which are hereby incorporated by reference.

In some embodiments, the resins in the dielectric film forming compositions described herein can include at least one (e.g., two or three) cyclic rubber. In some embodiments, the cyclized rubber is selected from a group of cyclized polydienes. In some embodiments, the cyclized polydienes include homopolymers of conjugated dienes such as isoprene, butadiene, and pentadiene. In other embodiments, the cyclized polydienes include copolymers of such conjugated dienes with olefins, styrene, or acrylates. In some embodiments, cyclization of rubber occurs under influence of heat, light, ultraviolet or nuclear radiation and/or in the presence of cation-donor catalysts (e.g., mineral acids, organic acids, or Lewis's acids). For example, two neighboring polymer structural units can participate in a cis olefin catalyzed cyclization to create a monocyclic structure, whilst one double bond will vanish. In general, bi- or tri-cyclic structures are created in later cyclization stages. Gradually, the unsaturation and elasticity are reduced as the result of successive cyclization of cis polydiene, and their toughness is increased. The cyclization is generally more efficient in polyisoprene than in polybutadiene. By controlling temperature, catalyst concentration and reaction time, a cyclization degree of from about 50% to about 95% can be achieved. Examples of such cyclization processes have been described in, e.g., U.S. Pat. Nos. 4,678,841 and 4,248,986, and European Patent No. 0063043, the contents of which are hereby incorporated by reference. These cyclized rubbers may be used alone or in combination of two or more kinds thereof. In some embodiments, the cyclized rubber is polyisoprene.

In some embodiments, the resins in the dielectric film forming compositions described herein can include at least one (e.g., two or three) cyanate ester compound (e.g., a cyanate ester compound having at least two cyanate groups in one molecule).

In some embodiments, the cyanate ester compounds described herein can have Structure (IX):

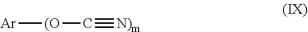

wherein m is an integer of at least 2 (m≥2) and Ar is a substituted or unsubstituted aromatic organic group wherein the cyanate ester groups are directly bonded to said substituted or unsubstituted aromatic organic group. In some embodiments, the aromatic organic group described above is optionally substituted by at least one (e.g., two or three) C₁-C₄ alkyl, halogen, C₁-C₄ haloalkyl, —OR′, —OC(O)R′, or —COOR′, where R′ is H, C₁-C₄ alkyl, C₅-C₁₂ cycloalkyl, C₆-C₁₈ aryl, or C₆-C₁₈ heteroaryl.

In some embodiments, the cyanate ester compounds described herein can have Structure (X):

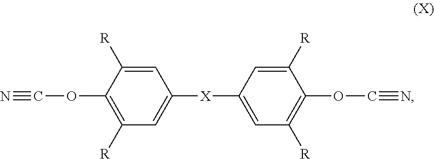

wherein R is a hydrogen atom, a C₁-C₃ alkyl group, a fully or partially halogen substituted C₁-C₃ alkyl group, or a halogen atom; X is a single bond, an O or S atom, a —(C═O)—, —(C═O)—O—, —O—(C═O)—, —(S═O)—, —(SO₂)—, or —CH₂CH₂—O— group, a substituted or unsubstituted C₁-C₁₀ alkylene group, a partially or fully fluoro substituted C₁-C₄ alkylene group, or a substituted or unsubstituted C₃-C₁₀ cycloalkylene group.

Specific examples of suitable cyanate ester compounds can include 2-bis(4-cyanatophenyl)propane, hexafluorobisphenol A dicyanate, bis(4-cyanate-3,5-dimethylphenyl)methane, 1,3-bis(4-cyanatephenyl-1-(methylethylidene))benzene, bis(4-cyanatephenyl)thioether, bis(4-cyanatephenyl)ether, and a polyfunctional cyanate resin derived from a phenol novolac, cresol novolac, or dicyclopentadiene-containing phenol resin. Other examples of such cyanate ester compounds have been described in, e.g., U.S. Pat. Nos. 3,595,900, 4,894,414, and 4,785,034 and U.S. Application Publication Nos. 2022/0002463 and 2022/0127459, the contents of which are hereby incorporated by reference. In some embodiments, although the weight average molecular weight of a cyanate ester resin or polymer is not particularly limited, it is from at least about 500 Daltons (e.g., at least about 600 Daltons) to at most about 4,500 Daltons (e.g., at most about 3,000 Daltons).

Without wishing to be bound by theory, it is believed that the cyanate ester compound can be cyclized and/or crosslinked thermally or under irradiation (e.g., with or without a catalyst) to form an interpenetrating network with the dielectric polymer in the dielectric film forming compositions described herein. Further, without wishing to be bound by theory, it is believed that including a cyanate ester compound in a dielectric film forming composition described herein can lower the dielectric constant (K) and/or dissipation factor (DF) of the film formed from the composition.

In some embodiments the resin of the disclosure is a polyimide precursor. In some embodiments the polyimide precursor is a heterocycle-containing polyimide precursor, wherein the heterocycle-containing polymer precursor is selected from a polyimide (PI) precursor comprising Formula (3)

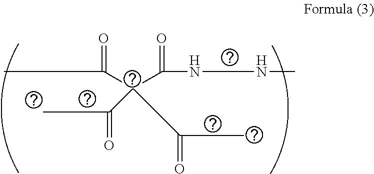

wherein A1 and A2 each independently represent an oxygen atom or NH, R111 represents a divalent organic group, R115 represents a tetravalent organic group, and R113 and R114 each independently represent a hydrogen atom or a monovalent organic group

In some embodiments, the amount of the resin or dielectric polymer is at least about 0.1 wt % (e.g., at least about 0.5 wt %, at least about 1 wt %, at least about 2 wt %, at least about 5 wt %, at least about 10 wt %, at least about 15 wt %, or at least about 20 wt %) and/or at most or about 55 wt % (e.g., at most about 50 wt %, at most about 45 wt %, at most about 40 wt %, at most about 35 wt %, at most about 30 wt %, at most about 25 wt %, at most about 20 wt %, at most about 15 wt %, or at most about 10 wt %) of the solid weight of the dielectric film forming compositions described herein.

In some embodiments, the dielectric film forming compositions described herein can include at least one (e.g., two, three, or four) photoacid generator or photobase generator, or a mixture of at least one photoacid generator and at least one photobase generator. For example, when a dielectric film forming composition includes a photosensitive polymer having an acid labile functional group, the composition can be include a photoacid generator (such as those described above) to remove the acid labile function groups and create a solubility contrast. As another example, when a dielectric film forming composition includes a photosensitive polymer having a base labile functional group (e.g., an epoxy group), the composition can be include a photobase generator to remove the base labile function groups to create a solubility contrast. Examples of suitable photobase generators include 9-anthrylmethyl N,N-diethylcarbamate (WPBG-018), 1,2-dicyclohexyl-4,4,5,5-tetramethylbiguanidium, n-butyltriphenylborate (WPBG-300), and the like. In some embodiments, the photoacid generator or photobase generator described herein can be in an amount of from at least about 0.1 wt % (e.g., at least about 0.2 wt %, at least about 0.4 wt %, at least about 0.5 wt %, at least about 0.6 wt %, at least about 0.8 wt %, or at least about 1 wt %) to at most about 5 wt % (e.g., at most about 4 wt %, at most about 3 wt %, at most about 2 wt %, or at most about 1 wt %) of the solid weight of a dielectric film forming composition described herein.

In some embodiments, the dielectric film forming compositions described herein can optionally further include an organic solvent or a mixture (e.g., two, three, or four) of organic solvents. Examples of organic solvents suitable for the dielectric film forming compositions described herein include, but are not limited to, alkylene carbonates such as ethylene carbonate, propylene carbonate, butylene carbonate, and glycerine carbonate; lactones such as gamma-butyrolactone, ε-caprolactone, γ-caprolactone and γ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; ether ester such as (tetrahydrofuran-2-yl)methyl acetate, methyl-3-methoxypropionate, ethyl-3-ethoxypropionate and 3-methoxy butyl acetate; glycol esters such as propylene glycol methyl ether acetate; glycol ethers such as propylene glycol methyl ether (PGME); cyclic ethers such as tetrahydrofuran (THF); pyrrolidones such as N-methyl-2-pyrrolidone, N-ethyl-2-pyrrolidone or N-butyl-2-pyrrolidone or TamiSolve™ N×G; and dialkyl sulfoxide such as dimethyl sulfoxide.

In some embodiments, the total amount of the solvent is at least about 20 wt % (e.g., at least about 25 wt %, at least about 30 wt %, at least about 35 wt %, at least about 40 wt %, at least about 45 wt %, at least about 50 wt %, at least about 55 wt %, at least about 60 wt %, or at least about 65 wt %) and/or at most about 98 wt % (e.g., at most about 95 wt %, at most about 90 wt %, at most about 85 wt %, at most about 80 wt %, at most about 75 wt %, at most about 70 wt %, or at most about 60 wt %) of the total weight of the dielectric film forming compositions described herein.

In some embodiments, the dielectric film forming compositions described herein optionally includes at least one (e.g., two, three, or four) filler (such as an inorganic filler or an inorganic particle). In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. In some embodiments, the inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 wt % (e.g., at least about 2 wt %, at least about 5 wt %, at least about 8 wt %, or at least about 10 wt %) and/or at most about 30 wt % (e.g., at most about 25 wt %, at most about 20 wt %, or at most about 15 wt %) of the solid weight of the dielectric film forming compositions described herein.

In some embodiments, the dielectric film forming compositions described herein can optionally further include at least one (e.g., two, three, or four) adhesion promoter. Suitable adhesion promoters are described in “Silane Coupling Agent” Edwin P. Plueddemann, 1982 Plenum Press, New York. Examples of such adhesion promoters are disclosed in, e.g., U.S. Pat. Nos. 10,036,952 and 10,563,014, and U.S. Application Publication No. 2015/0219990, and EP Patent No. 3,492, 982; the entire contents of which are hereby incorporated by reference.

In some embodiments, the amount of the optional adhesion promoter is at least about 0.5 wt % (e.g., at least about 0.8 wt %, at least about 1 wt %, or at least about 1.5 wt %) and/or at most about 4 wt % (e.g., at most about 3.5 wt %, at most about 3 wt %, at most about 2.5 wt %, or at most about 2 wt %) of the solid weight of the dielectric film forming compositions described herein.

In some embodiments, the dielectric film forming compositions described herein can optionally contain at least one (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the entire contents of which are hereby incorporated by reference.

In some embodiments, the amount of the surfactant is at least about 0.005 wt % (e.g., at least about 0.01 wt % or at least about 0.1 wt %) and/or at most about 1 wt % (e.g., at most about 0.5 wt % or at most about 0.2 wt %) of the solid weight of the dielectric film forming compositions described herein.

In some embodiments, the dielectric film forming compositions described herein can optionally contain at least one (e.g., two, three, or four) corrosion inhibitor. Examples of suitable corrosion inhibitors include triazole compounds, imidazole compounds and tetrazole compounds. Triazole compounds can include triazoles, benzotriazoles, substituted triazoles, and substituted benzotriazoles. Examples of triazole compounds include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups. Specific examples include benzotriazole, tolyltriazole, 5-methyl-1,2,4-triazole, 5-phenyl-benzotriazole, 5-nitro-benzotriazole, 3-amino-5-mercapto-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, and the like. Examples of imidazole include, but are not limited to, 2-alkyl-4-methyl imidazole, 2-phenyl-4-alkyl imidazole, 2-methyl-4(5)-nitroimidazole, 5-methyl-4-nitroimidazole, 4-Imidazolemethanol hydrochloride, and 2-mercapto-1-methylimidazole. Examples of tetrazole include 1-H-tetrazole, 5-methyl-1H-tetrazole, 5-phenyl-1H-tetrazole, 5-amino-1H-tetrazole, 1-phenyl-5-mercapto-1H-tetrazole, 5,5′-bis-1H-tetrazole, 1-methyl-5-ethyltetrazole, 1-methyl-5-mercaptotetrazole, 1-carboxymethyl-5-mercaptotetrazole, and the like. The amount of the optional corrosion inhibitor, if employed, is at least about 0.1 wt % (e.g., at least about 0.2 wt % or at least about 0.5 wt %) and/or at most about 3.0 wt % (e.g., at most about 2.0 wt % or at most about 1.0 wt %) of the solid weight of the dielectric film forming compositions described herein.

In some embodiments, the dielectric film-forming compositions described herein include other optional components, such as one or more (e.g., two, three, or four) dyes, pigments, plasticizers, or antioxidants. Examples of such components have been described, e.g., in U.S. Application Publication No. 2022/0127459, the entire contents of which are hereby incorporated by reference.

In some embodiments, a dielectric film can be prepared from a dielectric film forming composition described herein by a process containing the steps of: (a) coating the dielectric film forming composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods for preparation of the dielectric film include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In case of coating methods (1)-(11), the dielectric film forming composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments, the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns).

In some embodiments, when the dielectric film forming composition is photosensitive, the process to prepare a patterned photosensitive dielectric film includes converting the photosensitive dielectric film into a patterned dielectric film by a lithographic process. In such cases, the conversion can include exposing the photosensitive dielectric film to high energy radiation (such as electron beams, ultraviolet light, and X-ray) using a patterned mask.

After the exposure, the dielectric film can be heat treated from at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by use of an organic developer. Examples of such developers can include, but are not limited to, suitable organic solvents such as gamma-butyrolactone (GBL), gamma-valerolactone, cyrene, 2-methyl tetrahydrofuran, dimethyl sulfoxide (DMSO), N,N-diethylacetamide, methyl ethyl ketone (MEK), methyl isobutyl ketone (MIBK), 2-heptanone, cyclopentanone (CP), cyclohexanone, n-butyl acetate (nBA), propylene glycol methyl ether acetate (PGMEA), propylene glycol methyl ether (PGME), ethyl lactate (EL), propyl lactate, 3-methyl-3-methoxybutanol, tetralin, isophorone, ethylene glycol monobutyl ether, diethylene glycol monoethyl ether, diethylene glycol monoethyl ether acetate, diethylene glycol dimethyl ether, diethylene glycol methylethyl ether, triethylene glycol monoethyl ether, dipropylene glycol monomethyl ether, methyl 3-methoxypropionate, ethyl 3-ethoxypropionate, diethyl malonate, ethylene glycol, 1,4:3,6-dianhydrosorbitol, isosorbide dimethyl ether, 1,4:3,6-dianhydrosorbitol 2,5-diethyl ether (2,5-diethylisosorbide) and mixtures thereof. Preferred developers are gamma-valerolactone, cyrene, 2-methyl tetrahydrofuran, gamma-butyrolactone (GBL), cyclopentanone (CP), cyclohexanone, ethyl lactate (EL), n-butyl acetate (nBA) and dimethylsulfoxide (DMSO). These developers can be used individually or in combination of two or more to optimize the image quality for the composition and lithographic process.

In some embodiments, the dielectric film can be developed by using an aqueous developer. When the developer is an aqueous solution, it may contains one or more aqueous bases. Examples of suitable bases include, but are not limited to, inorganic alkalis (e.g., potassium hydroxide, sodium hydroxide), primary amines (e.g., ethylamine, n-propylamine), secondary amines (e.g., diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development by an organic developer, an optional rinse treatment can be carried out with an organic rinse solvent to remove residues. Suitable examples of organic rinse solvents include, but are not limited to, alcohols such as isopropyl alcohol, methyl isobutyl carbinol (MIBC), propylene glycol monomethyl ether (PGME), and amyl alcohol; esters such as n-butyl acetate (nBA), ethyl lactate (EL) and propylene glycol monomethyl ether acetate (PGMEA); ketnoes such as methyl ethyl ketone, and mixtures thereof.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or under a blanket of nitrogen and may be carried out by any suitable heating means.

In some embodiments, the patterned dielectric film includes at least one element having a feature size of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 micron). One important aspect of this disclosure is that the dielectric films prepared from the dielectric film forming composition described herein are capable of producing a patterned film with a feature size of at most about 3 microns (e.g., at most 2 microns or at most 1 micron) by a laser ablation process.

In some embodiments, the aspect ratio (ratio of height to width) of a feature (e.g., the smallest feature) of the patterned dielectric film of this disclosure is at least about ⅓ (e.g., at least about ½, at least about 1/1, at least about 2/1, at least about 3/1, at least about 4/1, or at least about 5/1).

In some embodiments (e.g., when the dielectric film forming composition is non-photosensitive), the process to prepare a patterned dielectric film include converting the dielectric film into the patterned dielectric film by a laser ablation technique. Direct laser ablation process with an excimer laser beam is generally a dry, one step material removal to form openings (or patterns) in the dielectric film. In some embodiments, the 20 wavelength of the laser is 640 nm or less (e.g., 157 nm, 193 nm, 248 nm, 308 nm, 351 nm, 405 nm, 445 nm, 470 nm, 520 nm, 528 nm, 555 nm, or 640 nm). Examples of suitable laser ablation processes include, but are not limited to, the processes described in US Patent Nos 7,598, 167, 6,667,551, and 6,114,240, the contents of which are hereby incorporated by reference.

In embodiments when the dielectric film forming composition is non-photosensitive, the composition can be used to form the bottom layer in a bilayer photoresist. In such embodiment, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a process for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. For example, the process can include the steps of: (a) depositing a dielectric film forming composition described herein on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a process to deposit a metal layer (e.g., an electrically conductive copper layer to create an embedded copper trace structure) on a semiconductor substrate. In some embodiment, to achieve this, a seed layer conformal to the patterned dielectric film is first deposited on the patterned dielectric film (e.g., outside the openings in the film). Seed layer can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-aspect-ratio) features. The fill factor by sputtering deposition has been improved by collimating the sputtered flux. Typically, this is achieved by inserting between the target and substrate a collimator plate having an array of hexagonal cells.

Next step in the process is metal seeding deposition. A thin metal (e.g., an electrically conductive metal such as copper) seeding layer can be formed on top of the barrier layer in order to improve the deposition of the metal layer (e.g., a copper layer) formed in the succeeding step.

Next step in the process is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. Nos. 5,891,804, 6,399,486, and 7,303,992, the contents of which are hereby incorporated by reference.

In some embodiments, the process of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron, or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017/0175274, the contents of which are hereby incorporated by reference.

Some embodiments describe a process for surrounding a metal structured substrate containing conducting metal (e.g., copper) wire structures forming a network of lines and interconnects with the dielectric film described herein. The process can include the steps of:
a) providing a substrate containing conducting metal wire structures that form a network of lines and interconnects on the substrate.
b) depositing a dielectric film forming composition described herein on the substrate to form a dielectric film (e.g., that surrounds the conducting metal lines and interconnects); and
c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method can include:
a) coating a carrier substrate (e.g., a substrate including at least one polymeric or plastic film) with a dielectric film forming composition described herein.
b) drying the coated dielectric film forming composition to form a dielectric layer (e.g., a photosensitive, dielectric layer); and
c) optionally, applying a protective layer to the dry film structure.

In some embodiments, the carrier substrate is a single or multiple layer polymeric or plastic film, which can include one or more polymers (e.g., polyethylene terephthalate). In some embodiments, the carrier substrate has excellent optical transparency, and it is substantially transparent to actinic irradiation used to form a relief pattern in the polymer layer. The thickness of the carrier substrate is in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

In some embodiments, the dielectric film of the dry film structure can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film forming composition described above except for the solvent.

In some embodiments, the dielectric loss tangent or dissipation factor of the dielectric film prepared from dielectric film forming composition described herein measured at 10 GHZ, 15 GHZ, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0.008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked dielectric film. In some embodiments, the carrier substrate can be removed before exposing the dielectric film to a source of radiation or heat.

Some embodiments of this disclosure describe a process of generating a planarizing dielectric film on a substrate with copper pattern. In some embodiments, the process includes depositing a dielectric film forming composition onto a substrate with copper pattern to form a dielectric film. In some embodiments, the process includes steps of:
a. providing a dielectric film forming composition of this disclosure, and
b. depositing the dielectric film forming composition onto a substrate with copper pattern to form a dielectric film, wherein the difference in the highest and lowest points on a surface of the dielectric film is at most about 2 microns (e.g., at most about 1.5 microns, at most about 1 micron, or at most about 0.5 micron).

In some embodiments, this disclosure features an article (or a three-dimensional object) containing at least one patterned dielectric film formed by a process described herein. Examples of such articles include a semiconductor substrate, a flexible film for electronics, a wire isolation, a wire coating, a wire enamel, and an inked substrate. In some embodiments, this disclosure features semiconductor devices that include one or more of these articles. Examples of semiconductor devices that can be made from such articles include an integrated circuit, a light emitting diode, a solar cell, and a transistor.

The contents of all publications cited herein (e.g., patents, patent application publications, and articles) are hereby incorporated by reference in their entirety.

The present disclosure is illustrated in more detail with reference to the following examples, which are for illustrative purposes and should not be construed as limiting the scope of the present disclosure.

### Synthesis Example 1: Preparation of Fully Imidized Polyimide (I)

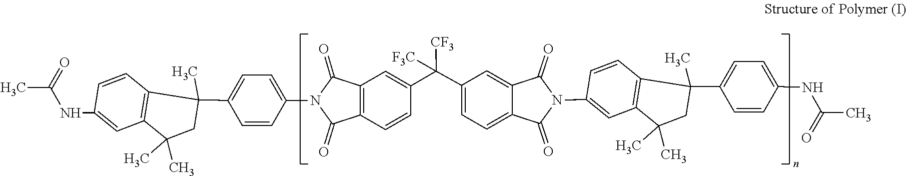

Solid 4,4′-(hexafluoroisopropylidene) bis(phthalic anhydride) (6FDA) (2.370 kg, 5.33 mole) was charged to a solution of 1-(4-aminophenyl)-1,3,3-trimethylindan-5-amine (also known as 4,4′-[1,4-phenylene-bis(1-methylethylidene)]bisaniline (DAPI)) (1.465 kg, 5.51 mole) in NMP (9.86 kg) at 25° C. The reaction mixture temperature was increased to 40° C. and allowed to react for 6 hours. Next, acetic anhydride (1.125 kg) and pyridine (0.219 kg) were added, and the reaction mixture temperature was increased to 100° C. and allowed to react for 12 hours.

The reaction mixture above was cooled to room temperature and transferred to a larger vessel equipped with a mechanical stirrer. The reaction solution was diluted with ethyl acetate and washed with water for one hour. After the stirring was stopped, the mixture was allowed to stand undisturbed. Once phase separation had occurred, the aqueous phase was removed. The organic phase was diluted with a combination of ethyl acetate and acetone and washed twice with water. The amounts of organic solvents (ethyl acetate and acetone) and water used in all of the washes are shown in Table 1.

TABLE 1

| | Wash 1 | Wash 2 | Wash 3 |
|---|---|---|---|
| Ethyl Acetate (kg) | 20.5 | 4.1 | 4.1 |
| Acetone (kg) | — | 2.3 | 2.3 |
| Water (kg) | 22.0 | 26.0 | 26.0 |

Cyclopentanone (10 kg) was added to the washed organic phase and the solution was concentrated by vacuum distillation to give a polymer solution containing polyimide (I) (FCP-1). The solid % of final polymer was 29.19% and the weight average molecular weight (Mw) measured by GPC was 54,000 Daltons.

### Synthesis Example 2: Preparation of Fully Imidized Polyimide (II)

The following is an example of preparation of a polyimide (PI) polymer using one diamine and one dianhydride wherein the isolation solvent (i.e., a lactone) was different from the purification solvents (i.e., a ketone and an ester).

Solid 4,4′-oxidiphthalic anhydride (ODPA, 664.5 g) was charged to a solution of 4,4′-diamino-2,2′-bis(trifluoromethyl)biphenyl (TFMB, 722.1 g) in NMP (3296 g) at 25° C. Additional NMP (1346 g) was used to rinse the dianhydride into the solution. The reaction temperature was increased to 40° C. and the mixture was allowed to react for 3 hours. Next, acetic anhydride (507.2 g) and pyridine (98.3 g) were added, the reaction temperature was increased to 100° C., and the mixture was allowed to react for 12 hours.

The reaction mixture was cooled to room temperature and a portion (899 g) was transferred to a 5-L vessel equipped with a mechanical stirrer. The reaction solution was diluted using a combination of cyclopentanone and n-butyl acetate and washed with water for one hour. Stirring was stopped and the mixture was allowed to stand undisturbed. Once phase separation had occurred, the aqueous phase was removed. The organic phase was diluted using cyclopentanone and washed three more times with water. The amounts of purification solvents (i.e., cyclopentanone and n-butyl acetate) and water used in all the washes are shown in Table 2.

TABLE 2

| | Wash 1 | Wash 2 | Wash 3 | Wash 4 |
|---|---|---|---|---|
| Cyclopentanone (g) | 1385 | 202 | — | — |
| n-Butyl Acetate (g) | 892 | — | — | — |
| Water (g) | 1329 | 1628 | 1631 | 1630 |

The washed organic phase was concentrated by vacuum distillation. Gamma-valerolactone (605 g) was added as an isolation solvent and vacuum distillation was continued. The final polymer solution contained polyimide (II) (FCP-2) at a concentration of 24.99 wt %.

### Synthesis Example 3: Preparation of Fully Imidized Polyimide (III)

Solid ODPA (14.73 g) was charged to a solution of TFMB (16.01 g) in 1:1 bioderived gama-valerolactone:cyrene (73.18 g) at 25° C. Additional 1:1 bioderived gama-valerolactone:cyrene (29.75 g) was used to rinse the dianhydride into the solution. The reaction temperature was increased to 40° C. and the mixture was allowed to react for 3 hours. Next, acetic anhydride (11.32 g) and pyridine (2.21 g) were added, the reaction temperature was increased to 100° C., and the mixture was allowed to react for 12 hours.

The processing method was followed by Example 2 and the polyimide (III) (FCP-3) thus formed was isolated in cyclopentanone.

### Synthesis Example 4: Preparation of Fully Imidized Polyimide (IV)

A mixture of solid ODPA (94.78 g) and 2,2-[bis(3,4-dicarboxyphenyl)] hexafluoropropane dianhydride (6FDA) (45.25 g) was charged to a solution of TFMB (135.5 g) in NMP (819 g) at 25° C. Additional NMP (100 g) was used to rinse the dianhydride into the solution. The reaction temperature was increased to 40° C. and the mixture was allowed to react for 3 hours. Next, acetic anhydride (94.25 g) and pyridine (18.27 g) were added, the reaction temperature was increased to 100° C., and the mixture was allowed to react for 12 hours.

The processing method was followed by Example 2 and the polyimide (IV) (FCP-4) thus formed was isolated in cyclopentanone.

### Synthesis Example 5: Preparation of Fully Imidized Polyimide (V)

A mixture of solid ODPA (117.6 g) and 2,2-[bis(3,4-dicarboxyphenyl)] hexafluoropropane dianhydride (6FDA) (8.87 g) was charged to a solution of TFMB (134.5 g) in NMP (819 g) at 25° C. Additional NMP (100 g) was used to rinse the dianhydride into the solution. The reaction temperature was increased to 40° C. and the mixture was allowed to react for 3 hours. Next, acetic anhydride (94.25 g) and pyridine (18.27 g) were added, the reaction temperature was increased to 100° C., and the mixture was allowed to react for 12 hours.

The processing method was followed by Example 2 and the polyimide (V) (FCP-5) thus formed was isolated in cyclopentanone.

### Photosensitive Composition Example 1

A photosensitive dielectric film forming composition (PSC-1) was prepared by using 100 parts of a 32% a solution of a polyimide polymer (V) having a weight average molecular weight of 51,000 Daltons in cyclopentanone (CPO), 44.26 parts of propylene carbonate (PC), 1.75 parts of a 0.5 wt % solution of PolyFox 6320 (a surfactant available from OMNOVA Solutions) in cyclopentanone, 1.46 parts of methacryloxypropyltrimethoxy silane (an adhesion promoter), 1.168 parts of Ivocerin (an acyl germanium photoinitiator), 0.06 parts of monomethyl ether hydroquinone (an antioxidant), 10.22 parts of tetraethylene glycol diacrylate (a reactive functional compound, Komerate D048), 1,46 parts of pentaerythritol triacrylate (a reactive functional compound, SR295), 0.15 parts of 5-methylbenzotriazole (a copper corrosion inhibitor), 2.92 parts of 2,2-bis(4-cyanatophenyl)propane (a cyanate ester in a 50% solution in cyclopentanone). After being stirred mechanically for 24 hours, the solution was filtered by using a 0.2-micron filter (Ultradyne from Meissner Corporation, cat #CLTM0.2-552).

### Photosensitive Composition Examples 2-5

Photosensitive dielectric film forming compositions 2-5 (i.e., PSC-2 to PSC-5) were prepared by using the same method described in Photosensitive Composition Example 1. The components and their amounts in these compositions are summarized in Table 3 below.

TABLE 3

| | Formulation | Formulation | Formulation | Formulation |
|---|---|---|---|---|
| | PSC-2 | PSC-3 | PSC-4 | PSC-5 |
| Component | Amount (g) | Amount (g) | Amount (g) | Amount (g) |
| FCP-5 in CPO (30.8% solid) | 167.05 | 167.05 | 167.05 | 167.05 |
| Komerate D048 | 18.01 | 18.01 | 18.01 | 18.01 |
| SR295 | 2.57 | 2.57 | 2.57 | 2.57 |
| 2,2-bis(4-cyanatophenyl)propane | 5.15 | 5.15 | 5.15 | 5.15 |
| 50% in CPO | | | | |
| methacryloxypropyltrimethoxy | 2.57 | 2.57 | 2.57 | 2.57 |
| silane | | | | |
| PolyFox 6320 in | 3.09 | 3.09 | 3.09 | 3.09 |
| Cyclopentanone | | | | |
| 5-methylbenzotriazole | 0.26 | 0.26 | 0.26 | 0.26 |
| Ivocerin | 2.57 | 1.54 | 1.54 | 1.02 |
| OXE 02 | None | None | 1.03 | None |
| NCI-831E | None | None | None | 0.52 |
| Monomethyl ether | 0.05 | 0.05 | 0.05 | 0.05 |
| hydroquinone | | | | |
| propylene carbonate | 48.68 | 48.68 | 48.68 | 48.68 |
| Cyclopentanone | 2.58 | 2.58 | 2.58 | 2.58 |

### Photosensitive Composition Example 6

A photosensitive dielectric film forming composition (PSC-6) is prepared by using 100 parts of a 32% a solution of a polyimide polymer (V) having a weight average molecular weight of 51,000 Daltons in cyclopentanone, 44.26 parts of propylene carbonate, 1.75 parts of a 0.5 wt % solution of PolyFox 6320 (a surfactant available from OMNOVA Solutions) in cyclopentanone, 1.46 parts of methacryloxypropyltrimethoxy silane (an adhesion promoter), 0.87 parts of Ivocerin (an acyl germanium photoinitiator), 0.29 parts of Irgacure 784 (a photoinitiator, available from BASF), 0.06 parts of monomethyl ether hydroquinone (an antioxidant), 10.22 parts of tetraethylene glycol diacrylate (a reactive functional compound, Komerate D048), 1,46 parts of pentaerythritol triacrylate (a reactive functional compound, SR295), 0.15 parts of 5-methylbenzotriazole (a copper corrosion inhibitor), 2.92 parts of 2,2-bis(4-cyanatophenyl)propane (a cyanate ester in a 50% solution in cyclopentanone). After being stirred mechanically for 24 hours, the solution is filtered by using a 0.2-micron filter (Ultradyne from Meissner Corporation, cat #CLTM0.2-552).

### Photosensitive Composition Example 7

A photosensitive dielectric film forming composition (PSC-7) is prepared by using 100 parts of a 29.19% a solution of a polyimide polymer (I) having a weight average molecular weight of 54,000 Daltons in cyclopentanone, 44.26 parts of cyclopentanone, 1.75 parts of a 0.5 wt % solution of PolyFox 6320 (a surfactant available from OMNOVA Solutions) in cyclopentanone, 1.46 parts of methacryloxypropyltrimethoxy silane (an adhesion promoter), 0.88 parts of Ivocerin (an acyl germanium photoinitiator), 0.06 parts of monomethyl ether hydroquinone (an antioxidant), 10.95 parts of tetraethylene glycol diacrylate (a reactive functional compound), 3.65 parts of pentaerythritol triacrylate (a reactive functional compound), 2.92 parts of 2,2-bis(4-cyanatophenyl)propane (a cyanate ester in a 50% solution in cyclopentanone), and 0.15 parts of 5-methylbenzotriazole (a copper corrosion inhibitor). After being stirred mechanically for 24 hours, the solution is filtered by using a 0.2-micron filter (Ultradyne from Meissner Corporation, cat #CLTM0.2-552).

### Photosensitive Composition Example 8

A photosensitive dielectric film forming composition (PSC-8) is prepared by using 100 parts of a 29.19% a solution of a polyimide polymer (I) (FCP-1) having a weight average molecular weight of 54,000 Daltons in cyclopentanone, 2.76 parts of cyclopentanone, 41.5 parts of bioderived gamma-valerolactone (GVL), 1.75 parts of a 0.5 wt % solution of PolyFox 6320 (a surfactant available from OMNOVA Solutions) in cyclopentanone, 1.46 parts of methacryloxypropyltrimethoxy silane (an adhesion promoter), 0.88 parts of Ivocerin (a germanium photoinitiator), 0.06 parts of monomethyl ether hydroquinone (an antioxidant), 10.95 parts of tetraethylene glycol diacrylate (a reactive functional compound), 3.65 parts of pentaerythritol triacrylate (a reactive functional compound), 2.92 parts of 2,2-bis(4-cyanatophenyl)propane (a cyanate ester in a 50% solution in cyclopentanone), and 0.15 parts of 5-methylbenzotriazole (a copper corrosion inhibitor). After being stirred mechanically for 24 hours, the solution is filtered by using a 0.2-micron filter (Ultradyne from Meissner Corporation, cat #CLTM0.2-552).

### Photosensitive Composition Example 9

A photosensitive dielectric film forming composition (PSC-9) is prepared by using 100 parts of a 29.19% a solution of a polyimide polymer (I) (FCP-1) having a weight average molecular weight of 54,000 Daltons in cyclopentanone, 2.76 parts of cyclopentanone, 41.5 parts of bioderived gamma-valerolactone (GVL), 1.75 parts of a 0.5 wt % solution of PolyFox 6320 (a surfactant available from OMNOVA Solutions) in cyclopentanone, 1.46 parts of methacryloxypropyltrimethoxy silane (an adhesion promoter), 0.88 parts of 2-(O-benzoyloxime)-1-[4-(phenylthio)phenyl]-1,2-octanedione (Irgacure OXE 01, a photoinitiator available from BASF), 0.22 parts of Ivocerin (an acyl germanium photoinitiator), 0.06 parts of monomethyl ether hydroquinone (an antioxidant), 10.95 parts of tetraethylene glycol diacrylate (a reactive functional compound), 3.65 parts of pentaerythritol triacrylate (a reactive functional compound), 2.92 parts of 2,2-bis(4-cyanatophenyl)propane (a cyanate ester in a 50% solution in cyclopentanone), and 0.15 parts of 5-methylbenzotriazole (a copper corrosion inhibitor). After being stirred mechanically for 24 hours, the solution is filtered by using a 0.2-micron filter (Ultradyne from Meissner Corporation, cat #CLTM0.2-552).

### Photosensitive Composition Example 10

A negative acting photosensitive dielectric film forming composition (PSC-10) is prepared by mixing 200 parts by weight EPON™ Resin SU-8 (40% weight in butyl carbitoi supplied by Hexion), 3 parts by weight of triethoxysilylpropyl ethoxycarbamate, parts by weight of TPS-C₁ supplied by Heraeus[Sulfonium triphenyl-, salt with tris[(trifluoromethyl)sulfonyl]-methane(1:1)], and 1 part by weight of Ivocerin, and filtered through a 0.2 micron Teflon filter.

A silicon wafer is then coated with the above photosensitive composition and baked for 3 minutes at 95° C. on a hotplate, resulting in a film. The film is exposed utilizing a 405 nm exposure tool with a patterned exposure array. The wafer is post exposure baked at 95° C. for 90 seconds. The wafer is developed with PGMEA using two 30 second puddle development steps with spin steps to remove spent developer in between applications of developer. The developed film is rinsed with n-butyl acetate and dried by spinning for 10 seconds at 5000 rpm to provide a relief pattern.

### Photosensitive Composition Example 11

A positive acting photosensitive composition is prepared by mixing 200 parts by weight of a polymer solution RD09-07 supplied by Fujifilm Electronic Materials U.S.A., 3 parts by weight of triethoxysilylpropyl ethoxycarbamate, 0.102 parts by weight of 1,8-diazabicyclo[5.4.0]undec-7-ene (DBU), 5 parts by weight of (5-propylsulfonyloxyimino-5H-thiophen-2-ylidene)-2-methylphenyl-acetonitrile and 1 parts of Ivocerin, 10 parts by weight tripropylene glycol, 20 parts by weight of additional PGMEA, and 30 parts by weight GBL, and filtered through a 0.2 micron Teflon filter.

A silicon wafer is then coated with the above photosensitive composition and baked for 3 minutes at 125° C. on a hotplate, resulting in a film. The film is exposed utilizing a 405 nm exposure tool with a patterned exposure array. The wafer is post exposure baked at 130° C. for 90 seconds. The wafer is developed with 2.38 wt % aqueous TMAH solution using two 30 second puddle development steps with spin steps to remove spent developer in between applications of developer. The developed film is rinsed with deionized water and dried by spinning for 10 seconds at 5000 rpm to provide a relief pattern.

### Photosensitive Composition Example 12

A dielectric film forming composition is prepared by mixing SC Rubber which is a cyclized polyisoprene and supplied by Fujifilm Electronic Materials U.S.A. (62.60 g in a 28.5 wt % solution in xylene), tricyclodecanedimethanol diacrylate (7.14 g, a reactive functional compound), and Ivocerin (0.53 g, a photoinitiator) to obtain a homogeneous solution. The solution is filtered by using a 5.0 microns PTFE filter.

A silicon wafer is then coated with the above photosensitive composition and baked for 3 minutes at 95° C. on a hotplate, resulting in a film. The film is exposed utilizing a 405 nm exposure tool with a patterned exposure array. The wafer is post exposure baked at 95° C. for 90 seconds. The wafer is developed with xylene using two 30 second puddle development steps with spin steps to remove spent developer in between applications of developer. The developed film is rinsed with PGMEA and dried by spinning for 10 seconds at 5000 rpm to provide a relief pattern.

### Photosensitive Composition Example 13

A photosensitive composition is prepared by mixing 28.48 g of PBO precursor polymer (I):

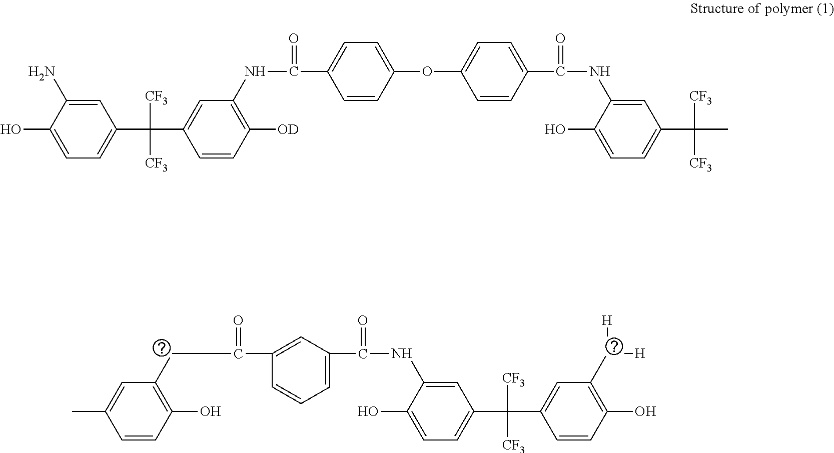

46.10 g of bioderived gamma-butyrolactone, 0.87 g of gamma-ureidopropyltrimethoxy-silane, 0.70 g of diphenyl silane diol, 3.85 g of PAC of Structure (II), and 0.56 g of Ivocerin. This composition is easily filtered using a 0.2 μm filter.

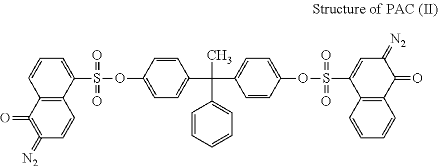

A silicon wafer is then coated with the above photosensitive composition and baked for 3 minutes at 95° C. on a hotplate, resulting in a film. The film is exposed utilizing a 405 nm exposure tool with a patterned exposure array. The wafer is post exposure baked at 130° C. for 90 seconds. The wafer is developed with 2.38 wt % aqueous TMAH solution using two 30 second puddle development steps with spin steps to remove spent developer in between applications of developer. The developed film is rinsed with deionized water and dried by spinning for 10 seconds at 5000 rpm to provide a relief pattern.

### Photosensitive Composition Example 14

A photosensitive composition is prepared by mixing 29.82 g of PD-1630 Polymer (Durite Resin supplied by Hexion), 5.06 g of PS-9 PAC (supplied by SEQENS), 0.052 g of Silwet L-7210 Surfactant, and 0.59 g of Ivocerin in 65 g of cyclopentanone. This composition is easily filtered using a 0.2 μm filter.

A silicon wafer is then coated with the above photosensitive composition and baked for 3 minutes at 95° C. on a hotplate, resulting in a film. The film is exposed utilizing a 405 nm exposure tool with a patterned exposure array. The wafer is post exposure baked at 130° C. for 90 seconds. The wafer is developed with 2.38 wt % aqueous TMAH solution using two 30 second puddle development steps with spin steps to remove spent developer in between applications of developer. The developed film is rinsed with deionized water and dried by spinning for 10 seconds at 5000 rpm to provide a relief pattern.

### Dry Film Example 1

A photosensitive dielectric film forming composition is prepared by using 1345.24 g of a 31.69% solution of a polyimide polymer (I) (FCP-1) having a weight average molecular weight of 54000 in cyclopentanone, 1021.91 g of bioderived gamma valerolactone (GVL), 102.31 g of a 0.5 wt % solution of PolyFox 6320 in cyclopentanone, 21.31 g of methacryloxypropyltrimethoxy silane, 34.11 g of a 50% solution of XU-378 (Bisphenol M Cyanate ester available from Huntsman) in cyclopentanone, 12.79 g of Ivocerin, 0.43 g of monomethyl ether hydroquinone, 138.55 g of tetraethylene glycol diacrylate, 53.39 g of pentaerythritol triacrylate, 21.32 g of ethylene glycol dicyclopentenyl ether acrylate, 4.26 g of dicumyl peroxide, and 0.426 g of 5-methyl benzotriazole. After being stirred mechanically for 24 hours, the solution is filtered by using a 0.2-micron filter (Ultradyne from Meissner Corporation, cat #CLTM0.2-552).

This photosensitive dielectric film forming composition obtained above is applied using a slot die coater with a line speed of about 2 feet/minute (61 cm per minute) with 60 microns clearance onto a polyethylene terephthalate (PET) film (TCH21, manufactured by DuPont Teijin Films USA) having a width of 16.2″ and thickness of 36 microns (which is used as a carrier substrate), and dried at 194ºF to obtain a photosensitive polymeric layer. On this polymeric layer, a biaxially oriented polypropylene film having a width of 16″ and a thickness of 30 microns (BOPP, manufactured by Impex Global, Houston, TX) is laid over by a roll compression to act as a protective layer. The carrier substrate, the photosensitive polymeric layer, and the protective layer together form a dry film (i.e., DF-1).

### Three-Dimensional Object Example 1

The photosensitive dielectric film forming composition described in Dry Film Example 1 is converted to films deposited on various substrates used in microelectronics and packaging applications. A film is deposited on a 100 mm silicon wafer by spin coating about 5 g of the solution at a spin speed of about 2000 rpm. The film is dried at a temperature of 105° C. for 3 minutes on a hotplate to obtain 12-micron clear and transparent film is obtained. Film quality in terms of transparency, defect count, and uniformity is expected to meet the requirements for semiconductor packaging applications.

The above procedures are repeated on aluminum, copper, and silicon nitride wafers. All films thus obtained are expected to meet the requirements for semiconductor packaging applications.

1. A dielectric film forming composition, comprising:
at least one resin; and
at least one acyl germanium compound.

2. The composition of claim 1, wherein the at least one acyl germanium compound comprises a compound of structure (I): 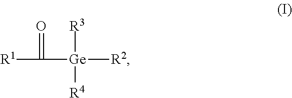
in which
R¹ is C₁-C₁₂ alkyl, C₂-C₁₂ alkenyl, C₄-C₁₈ cycloalkyl, C₆-C₂₂ aryl, or C₆-C₂₂ heteroaryl;
each of R², R³, and R⁴, independently, is C₁-C₁₂ alkyl, C₂-C₁₂ alkenyl, C₄-C₁₈ cycloalkyl, C₆-C₂₂ aryl, C₆-C₂₂ heteroaryl, or —C(O)R, in which R is C₁-C₄ alkyl, C₅-C₁₂ cycloalkyl, C₆-C₁₈ aryl, or C₆-C₁₈ heteroaryl; and
each of alkyl, alkenyl, cycloalkyl, aryl, or heteroaryl, independently, is optionally substituted by at least one C₁-C₄ alkyl, halogen, C₁-C₄ haloalkyl, —OR⁵, —OC(O)R⁵, or —COOR⁵, where R⁵ is H, C₁-C₄ alkyl, C₅-C₁₂ cycloalkyl, C₆-C₁₈ aryl, or C₆-C₁₈ heteroaryl.

3. The composition of claim 1, wherein the at least one acyl germanium compound comprises (2,4,6-trimethylbenzoyl)triethylgermanium, (2,4,6-trimethylbenzoyl)tripropylgermanium, (2,4,6-trimethylbenzoyl)tributylgermanium, (2,6-dimethoxybenzoyl)triethylgermanium, (2.6-dimethoxybenzoyl)tripropylgermanium, (2,6-dimethoxybenzoyl)tributylgermanium, bisbenzoyldiethylgermanium, bisbenzoyldipropylgermanium, bis(4-methoxybenzoyl)diethylgermanium, bis(2,4,6-trimethylbenzoyl)diethylgermanium, trisbenzoylethylgermanium, tris(2,4,6-trimethylbenzoyl)ethylgermanium.

4. The composition of claim 1, wherein the at least one acyl germanium compound is in an amount of from about 0.05% to about 20% by weight based on the solid weight of the composition.

5. The composition of claim 1, further comprising at least one radical initiator different from the acyl germanium compound.

6. The composition of claim 5, wherein the at least one radical initiator comprises an oxime ester.

7. The composition of claim 6, wherein the radical initiator is an oxime ester of structure (II): 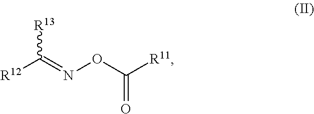
wherein
each of R¹¹ and R¹², independently, is substituted or unsubstituted C₁-C₁₂ alkyl, substituted or unsubstituted C₄-C₁₈ cycloalkyl, substituted or unsubstituted C₆-C₂₂ aryl, or substituted or unsubstituted C₆-C₂₂ heteroaryl; and
R¹³ is a UV absorbing functional group.

8. The composition of claim 5, wherein the at least one radical initiator comprises the compound of structure (III): 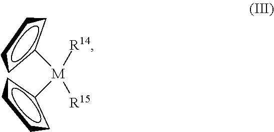
wherein
M is a metal selected from the group consisting of titanium, zirconium, or hafnium; and
each of R¹⁴ and R¹⁵, independently, is selected from the group consisting of substituted or unsubstituted C₁-C₁₂ alkyl, substituted or unsubstituted C₄-C₁₈ cycloalkyl, substituted or unsubstituted C₆-C₂₂ aryl, substituted or unsubstituted C₆-C₂₂ heteroaryl, and substituted or unsubstituted alkylsulfonyloxy group.

9. The composition of claim 1, wherein the at least one resin comprises a fully imidized polyimide optionally containing a functional group; a cyclized rubber; a cyclic olefin polymer optionally containing a functional group; a polyphenylene ether; an acrylic compound; a cyanate ester compound; a polybenzoxazole precursor polymer; a novolac polymer; an epoxy phenol novolac polymer; or an alkaline soluble polyimide.

10. The composition of claim 1, wherein the at least one resin is in an amount of from about 0.1% to about 55% by weight based on the solid weight of the composition.

11. The composition of claim 1, further comprising at least one ethylenically unsaturated polymerizable compound, at least one thiol compound, at least one siloxane compound, at least one metal-containing (meth)acrylate compound, or mixtures thereof.

12. The composition of claim 1, further comprising a photosensitizer selected from the group consisting of benzophenones, thioxanthones, anthraquinones, anthracenes, and coumarines.

13. The composition of claim 1, further comprising at least one photoacid generator or photobase generator, or a mixture of at least one photoacid generator and at least one photobase generator.

14. The composition of claim 1, further comprising at least one adhesion promoter, at least one corrosion inhibitor, at least one surfactant, at least one filler, at least one pigment, at least one dye, or a mixture thereof.

15. A process for preparing a patterned dielectric film, comprising:
a) depositing the dielectric film forming composition of claim 1 on a substrate to form a dielectric film;
b) exposing the dielectric film to radiation or heat or a combination of radiation or heat; and
c) patterning the dielectric film to form a patterned dielectric film having openings.

16. A patterned dielectric film produced by the process of claim 15.

17. A three-dimensional object, comprising at least one patterned dielectric film of claim 16 and at least one substrate.

18. The three-dimensional object of claim 17, wherein the substrate comprises an organic film, an epoxy molded compound (EMC), silicon, glass, copper, stainless steel, a copper cladded laminate (CCL), aluminum, silicon oxide, silicon nitride, or a combination thereof.

19. The three-dimensional object of claim 18, wherein the substrate comprises a metal pattern.

20. A process for preparing a three dimensional object, comprising:
a) depositing the dielectric film forming composition of claim 1 on a substrate to form a dielectric film;
b) exposing the dielectric film to radiation or heat or a combination of radiation or heat;
c) patterning the dielectric film to form a patterned dielectric film having openings;
d) optionally depositing a seed layer on the patterned dielectric film; and
e) depositing a metal layer in at least one opening in the patterned dielectric film to form a metal pattern.

21. The process of claim 20, wherein the patterned dielectric film comprises surrounding copper patterns.

22. A process for forming a three-dimensional object, comprising:
a) providing a substrate containing metal wire structures that form a network of lines and interconnects on the substrate;
b) depositing the dielectric film forming composition of claim 1 on the substrate to form a dielectric film; and
c) exposing the dielectric film to radiation or heat or a combination of radiation and heat.

23. A semiconductor device, comprising the three-dimensional object of claim 17.

24. The semiconductor device of claim 23, wherein the semiconductor device is an integrated circuit, a light emitting diode, a solar cell, or a transistor.

25. A dry film structure, comprising:
a carrier layer; and
a dielectric film supported by the carrier layer, the dielectric film being prepared from the composition of claim 1.

26. A process for preparing a dry film structure, comprising:
(a) coating a carrier substrate with the composition of claim 1 to form a coated composition;
(b) drying the coated composition to form a dielectric layer; and
(c) optionally applying a protective layer to the dielectric layer to form the dry film structure.

27. The process of claim 26, further comprising:
applying the dry film structure onto an electronic substrate to form a laminate, wherein the dielectric layer in the laminate is between the electronic substrate and the carrier substrate.

28. A process of generating a dielectric film on a substrate having a copper pattern, comprising:
depositing the composition of claim 1 onto a substrate having a copper pattern to form a dielectric film,
wherein the difference in height between the highest and lowest points on a surface of the dielectric film is at most about 2 microns.
